(19) United States
(12) Patent Application Publication
(10) Pub. No.: US 2015/0151871 A1
(43) Pub. Date: Jun. 4, 2015

(54) SELF-SUPPORTING PROTECTIVE CASE FOR ELECTRONIC DEVICE

(71) Applicant: HON HAI PRECISION INDUSTRY CO., LTD., NEW TAIPEI (TW)

(72) Inventor: FU-KUO HUANG, New Taipei (TW)

(21) Appl. No.: 14/517,530

(22) Filed: Oct. 17, 2014

(30) Foreign Application Priority Data
Nov. 30, 2013 (CN) 2013106224834

(51) Int. Cl. B65D 5/52; H05K 5/00

(52) U.S. Cl. CPC B65D 5/5206; H05K 5/0086

(57) ABSTRACT

A self-supporting protective case includes a shell and a movable cover. The shell defines a cavity for holding an electronic device. The cavity has a plurality of edges. The cover is attached to one of the plurality of cavity edges. The cover includes a connecting portion and a cover portion. The cover portion includes a foldably connected section, and a supporting portion. The cavity is coverable by the cover portion of the cover. The supporting comprises a first supporting block and a second supporting block. A first angle is defined between the first supporting block and the second supporting block. The foldably connected section is foldable to change the first angle and to enable the first supporting block and the second supporting block to be a support for the shell.

### CROSS-REFERENCE TO RELATED APPLICATIONS

This application claims priority to Chinese Patent Application No. 201310622483.4 Nov. 30, 2013 in the China Intellectual Property Office, the contents of which are incorporated by reference herein.

### FIELD

The subject matter herein generally relates to a self-supporting protective case for protecting an electronic device.

### BACKGROUND

A self-supporting protective case is used to protect an electronic device from damage of normal use.

### BRIEF DESCRIPTION OF THE DRAWINGS

Implementations of the present technology will now be described, by way of example only, with reference to the attached figures.

FIG. 1 is an exploded, isometric view of an embodiment of a self-supporting protective case for an electronic device.

FIG. 2 is similar to FIG. 1, but viewed in a different angle.

FIG. 3 is an assembled view of the self-supporting protective case of FIG. 1.

FIG. 4 is similar to FIG. 1, but a cover is open.

FIG. 5 is an isometric view of the self-supporting protective case of FIG. 3 in use, where a supporting portion supports a shell to a first position.

FIG. 6 is similar to FIG. 5, where the supporting portion supports the shell to a second position.

FIG. 7 is similar to FIG. 5, where the supporting portion supports the shell to a third position.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “outside” refers to a region that is beyond the outermost confines of a physical object. The term “inside” indicates that at least a portion of a region is partially contained within a boundary formed by the object. The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other feature that the term modifies, such that the component need not be exact. For example, substantially cylindrical means that the object resembles a cylinder, but can have one or more deviations from a true cylinder. The term “comprising,” when utilized, means “comprising, but not necessarily limited to”; it specifically indicates open-ended inclusion or membership in the so-described combination, group, series and the like.

The present disclosure is described in relation to a self-supporting protective case for protection of an electronic device.

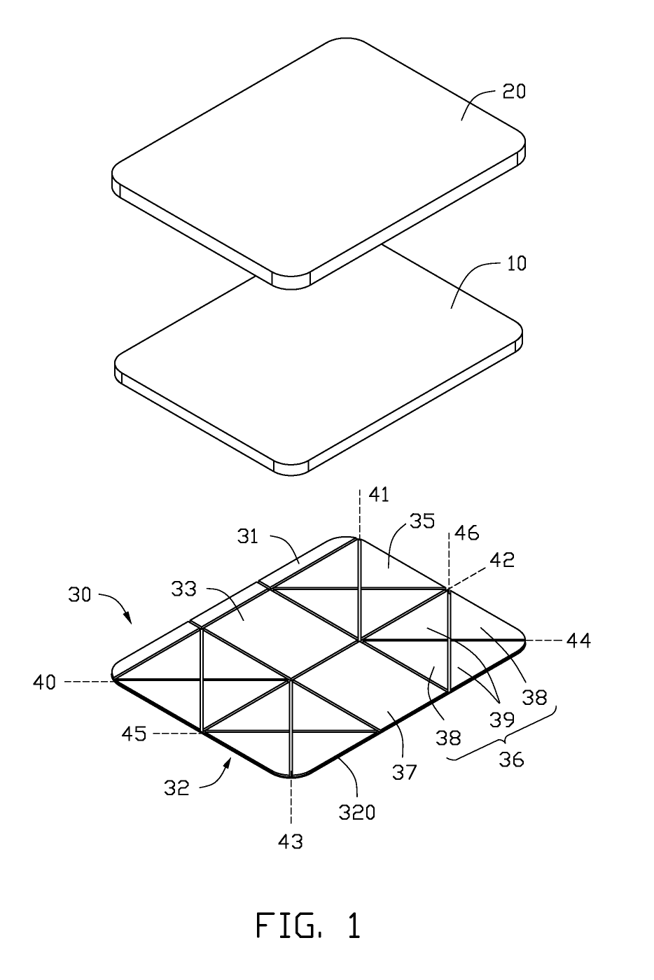

FIG. 1 illustrates an embodiment of a self-supporting protective case for an electronic device. The self-supporting protective case comprises a shell 20 for receiving an electronic device 10 and a movable cover 30. In one embodiment, the electronic device 10 is a mobile phone or a computer.

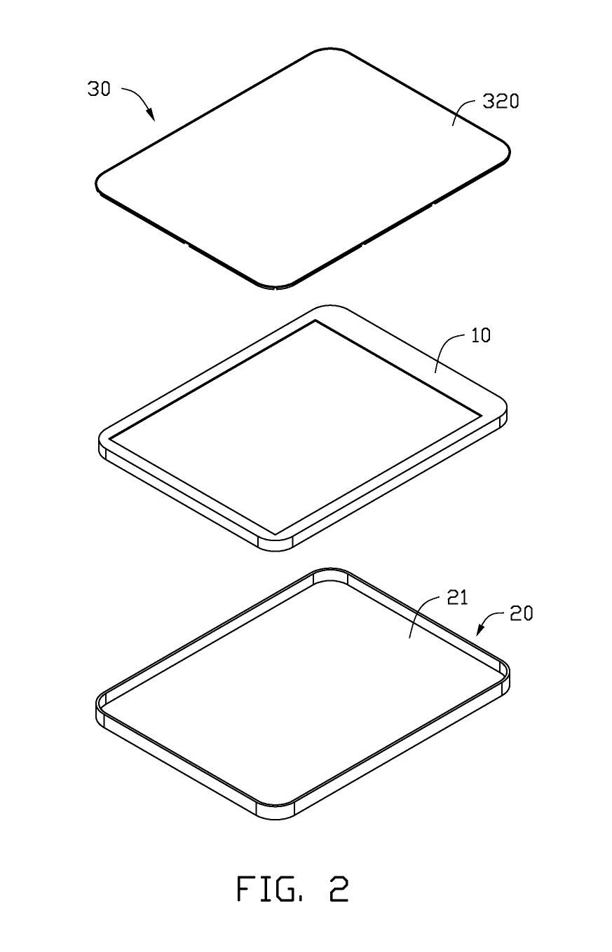

FIG. 2 illustrates that the shell 20 comprises a cavity 21 for receiving the electronic device 10. The shell 20 is hollow. The cavity 21 has a plurality of edges.

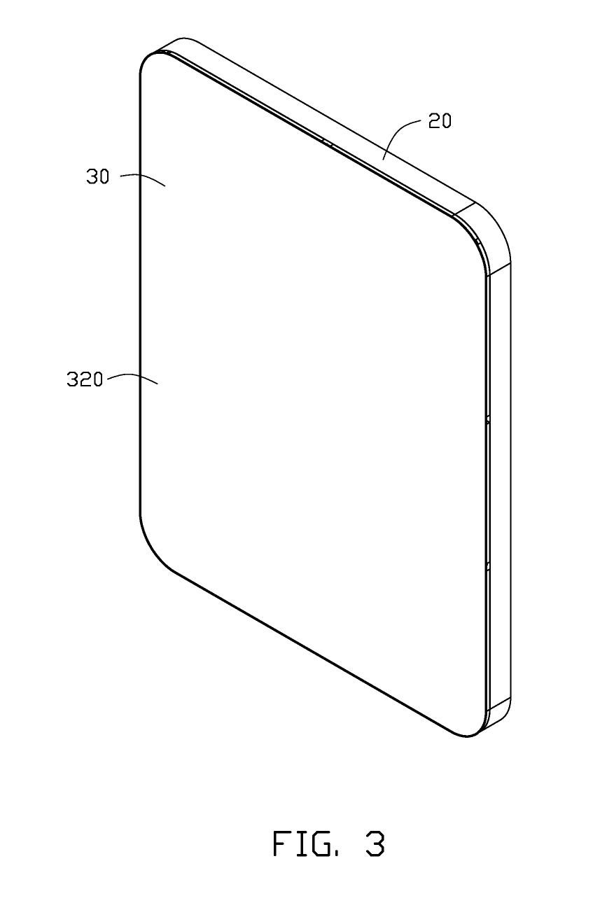

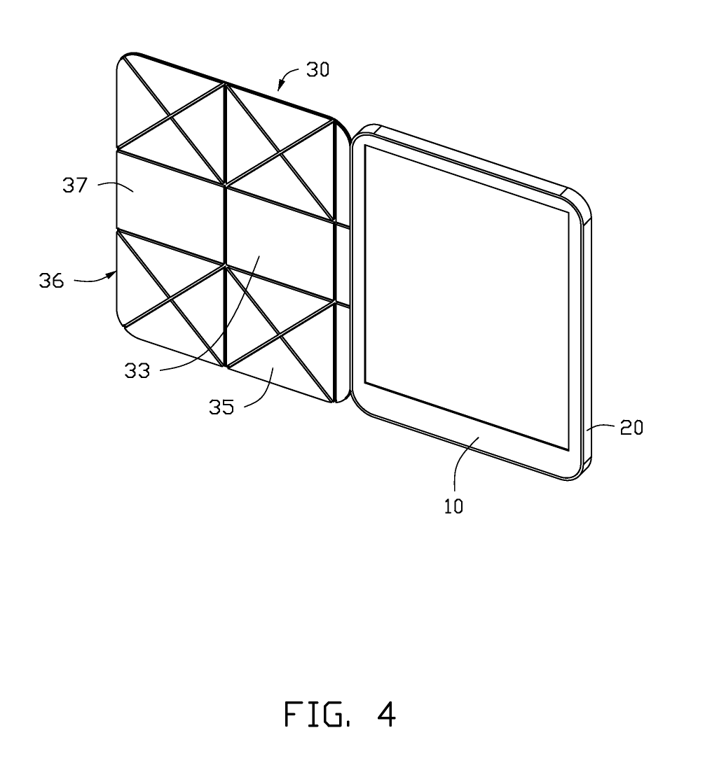

FIGS. 3 and 4 illustrate that the cover 30 comprises a connecting portion 31 coupled to an edge of the cavity 21 and a cover portion 32 movably coupled to the connecting portion 31. The cover portion 32 is configured to cover the cavity 21 to protect the electronic device 10. In one embodiment, the connecting portion 31 is soft material.

The cover portion 32 comprises a base 33 and a supporting portion 34 mounted in the inside of the section 320. The cover portion 32 further comprises a foldably connected section 320 for covering the cavity 21. The supporting portion 34 is mounted in the inside of the section 320. In one embodiment, the foldably connected section 320 are soft material; the base 33 and the supporting portion 34 are magnetic; the cover portion 32 is substantially square; and the base 33 is substantially isosceles trapezoid. The supporting portion 34 comprises two bent portions 35, two folding portions 36, and a bottom portion 37. The two bent portions 35 are located outside of the base 33. The bottom portion 37 is located between the two folding portions 36. Each bent portion 35 is located between the base 33 and one corresponding folding portion 36. The bent portions 35 are substantially a right angled isosceles triangle. The bottom portion 37 is substantially square. The two bent portions 35 can be folded along a first straight line 40 and a second straight line 41, respectively. The supporting portion 34 can be folded along a third straight line 42. Each folding portion 36 is substantially square. The two folding portions 36 can be folded along a first diagonal 43 and a second diagonal 44, respectively. The two folding portions 36 are folded to be right angled isosceles triangles and substantially perpendicular to the base 33. The two folding portions 36 can be folded along a third diagonal 45 and a fourth diagonal 46, respectively. Each folding portion 36 comprises two first supporting blocks 38 and two second supporting blocks 39. A first angle is defined between the first supporting blocks 38 and the corresponding second supporting blocks 39 when the first supporting blocks 38 and the corresponding second supporting blocks 39 are folded. The first angle is greater than 0° and less than 180°. When the first angle is 0°, the first supporting blocks 38 are coincident with the corresponding second supporting blocks 39. When the first angle is 180°, the first supporting blocks 38 and the corresponding second supporting blocks 39 are at the same level. In one embodiment, the second straight line 41 is substantially parallel to the first diagonal 43; the first straight line 40, the second diagonal 44, and the third diagonal 45 are substantially parallel to each other; the first straight line 40, the second diagonal 44, and the third diagonal 45 are substantially perpendicular to both the second straight line 41 and the first diagonal 43; a third angle between the third straight line 42 and the first straight line 40 is 45°; a fourth angle between the third straight line 42 and the second diagonal 44 is 45°; a fifth angle between the third straight line 42 and the third diagonal 45 is 45°; a sixth angle between the third straight line 42 and the fourth diagonal is 45°.

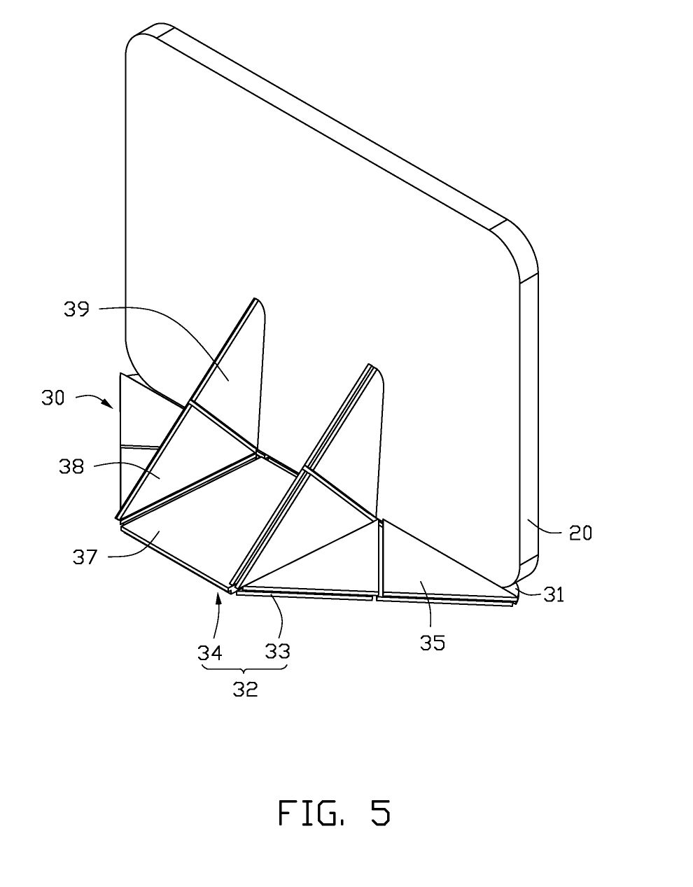

FIGS. 1 and 5 illustrate that in use, the two first bent portions 35 are folded along the first straight line 40 and the second straight line 41, respectively. The first bent portions 35 are coincident with the base 33. The supporting portion 34 is folded along the third straight line 42. The bottom portion 37 is coincident with the base 33. The two folding portions 36 are folded along the first diagonal 43 and the second diagonal 44. The first supporting blocks 38 of the corresponding folding portions 36 and the second supporting blocks 39 of the folding portions 36 are at the same level. The first supporting blocks 38 are supported on the base 33 and are substantially perpendicular to the base 33. A first edge of the second supporting blocks 39 supports the shell 20 to a first position. A second angle is defined between the shell 20 and the base 33.

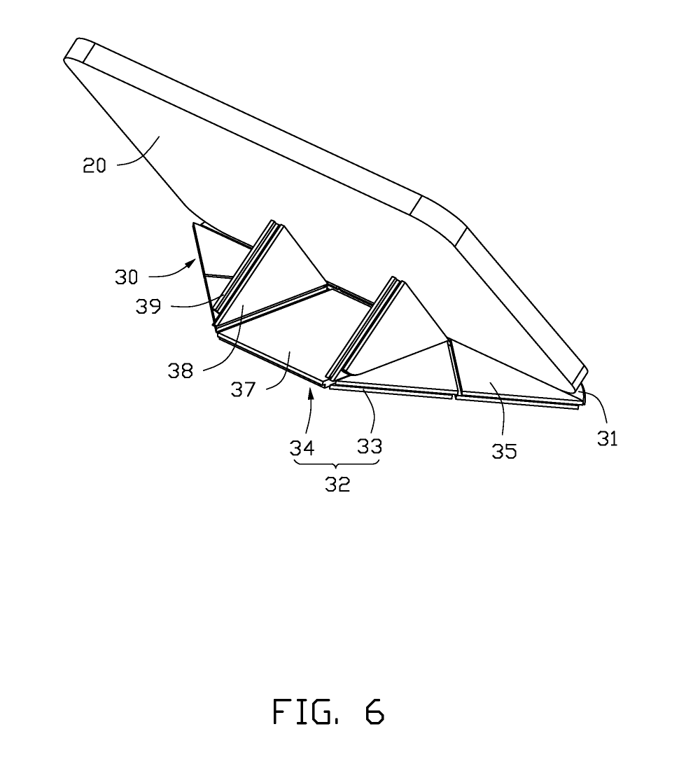

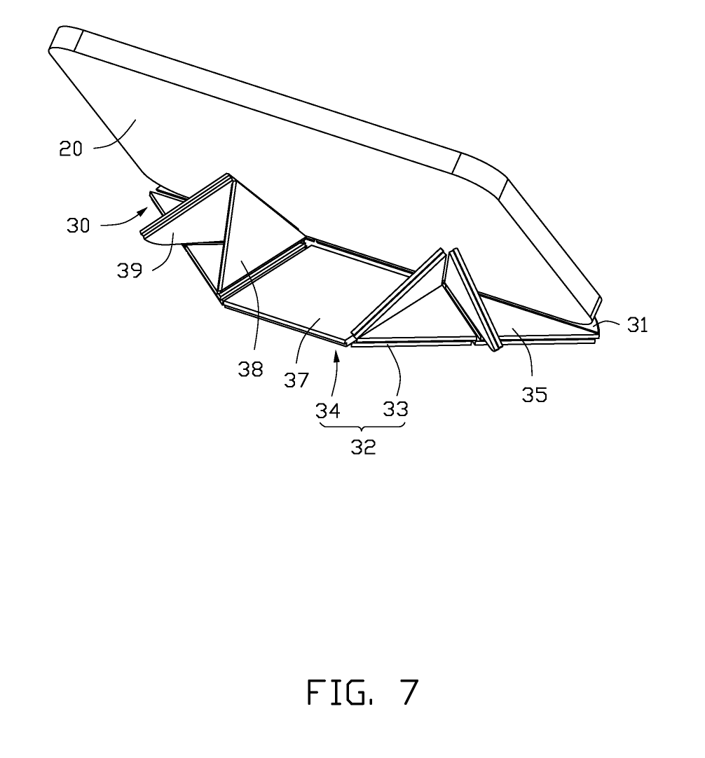

FIGS. 1, 6, and 7 illustrate that the two folding portions 36 are folded along the third diagonal 45 and the fourth diagonal 46, respectively. When the first supporting blocks 38 of the corresponding folding portion 36 are coincident with the second supporting blocks 39 of the corresponding folding portion 36, a second edge of the corresponding first supporting blocks 38 and a third edge of the corresponding second supporting blocks 39 support the base 33, the first edge of the corresponding first supporting blocks 38 and a fourth edge of the corresponding second supporting blocks 39 support the shell 20 in a second position; the first supporting blocks 38 and the second supporting blocks 39 are substantially perpendicular to the base 33; and the second angle decreases. When the first angle is greater than 0° and less than 180°, the second edge of the corresponding first supporting blocks 38 and the third edge of the corresponding second supporting blocks 39 support the base 33, the first edge of the corresponding first supporting blocks 38 and the fourth edge of the corresponding second supporting blocks 39 support the shell 20 to a third position; and the second angle further decreases. In one embodiment, the second angle increases when the first angle decreases.

In the embodiment, users can fold the folding portion 36 along different diagonals to change the first angle; thereby changing the second angle, thus the supporting portion 34 supports the shell 20 in different positions. It is convenient to use the electronic device 10.

It is to be understood that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A self-supporting protective case for an electronic device comprising:
a shell defining a cavity for holding an electronic device, the cavity having a plurality of edges; and
a movable cover attached to one of the plurality of cavity edges, the cover having a connecting portion connected to the shell and a cover portion connected to the connecting portion, the cover portion comprising a foldably connected section and a supporting portion mounted to the section;
wherein, the cavity is coverable by the cover portion of the cover;
wherein, the supporting comprises a first supporting block and a second supporting block, a first angle is defined between the first supporting block and the second supporting block; and
wherein, the foldably connected section of the cover portion is foldable to change the first angle and to enable the first supporting block and the second supporting block to be a support for the shell.

2. The self-supporting protective case of claim 1, wherein the cover section further comprises a base mounted to the section, a second angle is defined between the receiving shell and the base, the foldably connected section is foldable to change the first angle, thereby changing the second angle.

3. The self-supporting protective case of claim 2, wherein when the first angle is 180°, the first supporting block and the second supporting block are at the same level; the first supporting block supports the base; and the second supporting block supports the shell to a first position.

4. The self-supporting protective case of claim 2, wherein when the first angle is 0°, the first supporting block is coincident with the second supporting block; the first supporting block and the second supporting block support the base and support the shell to a second position.

5. The self-supporting protective case of claim 2, wherein the supporting portion further comprises two bent portions, another first supporting block, and another second supporting block; the bottom portion is located between the two first supporting blocks; each bent portion is located between one corresponding first supporting block and the base; each bent portion is folded to be coincident with the base; and the bottom portion is folded to be coincident with the base.

6. The self-supporting protective case of claim 5, wherein the two bent portions are folded along a first straight line and a second straight line, to be coincident with the base; and the first straight line is substantially perpendicularly to the second straight line.

7. The self-supporting protective case of claim 5, wherein the bottom portion is folded to be coincident with the base after the supporting portion is folded along a first straight line; the first supporting block is fold along a diagonal; and a third angle between the first straight line and the diagonal is 45°.

8. The self-supporting protective case of claim 5, wherein one of the bent portions is folded along the first straight line to be coincident with the base; the bottom portion is folded along the second straight line to be coincident with the base; and a fourth angle between the first straight line and the second straight line is 45°.

9. The self-supporting protective case of claim 2, wherein the second angle decreases when the first angle decreases from 180° to 0°.

10. The self-supporting protective case of claim 2, wherein the base is substantially isosceles trapezoid.

11. A self-supporting protective case for an electronic device comprising:
a shell defining a cavity for holding an electronic device, the cavity having a plurality of edges; and
a movable cover attached to one of the plurality of cavity edges, the cover having a connecting portion connected to the shell and a cover portion connected to the connecting portion, the cover portion comprising a foldably connected section, a base mounted to the section, and a supporting portion mounted to the section;
wherein, the cavity is coverable by the cover portion of the cover;
wherein, the supporting comprises two first supporting blocks and two second supporting block, a first angle is defined between the two first supporting blocks and the two second supporting blocks, a second angle is defined between the receiving shell and the base; and
wherein, the foldably connected section of the cover portion is foldable to change the first angle and the second angle, and to enable the first supporting blocks and the second supporting blocks to be a support for the shell.

12. The self-supporting protective case of claim 11, wherein when the first angle is 180°, the first supporting block and the second supporting block are at the same level; the first supporting block supports the base; and the second supporting block supports the shell to a first position.

13. The self-supporting protective case of claim 11, wherein when the first angle is 0°, the first supporting block is coincident with the second supporting block; the first supporting block and the second supporting block support the base and support the shell to a second position.

14. The self-supporting protective case of claim 11, wherein the supporting portion further comprises two bent portions, another two first supporting blocks, and another two second supporting block; the bottom portion is located between the four first supporting blocks; each bent portion is located between one corresponding first supporting block and the base; each bent portion is folded to be coincident with the base; and the bottom portion is folded to be coincident with the base.

15. The self-supporting protective case of claim 14, wherein the two bent portions are folded along a first straight line and a second straight line, to be coincident with the base; and the first straight line is substantially perpendicular to the second straight line.

16. The self-supporting protective case of claim 14, wherein the bottom portion is folded to be coincident with the base after the supporting portion is folded along a first straight line; one of the first supporting blocks is folded along a first diagonal; and a third angle between the first straight line and the first diagonal is 45°.

17. The self-supporting protective case of claim 14, wherein one of the bent portions is folded along a first straight line to be coincident with the base; the bottom portion is folded along a second straight line to be coincident with the base; one of the first supporting blocks is folded along a second diagonal; and a fourth angle between the first straight line and the second diagonal is 45°.

18. The self-supporting protective case of claim 17, wherein a fifth angle between the second straight line and the second diagonal is 45°.

19. The self-supporting protective case of claim 11, wherein the second angle decreases when the first angle decreases from 180° to 0°.

20. The self-supporting protective case of claim 11, wherein the first supporting block is substantially right angled isosceles triangle.
